(19) United States
(12) Patent Application Publication
(10) Pub. No.: US 2026/0127342 A1
(43) Pub. Date: May 7, 2026

(54) DESIGN METHOD FOR SUPERCRITICAL CARBON DIOXIDE COMPRESSOR

(71) Applicant: Nuclear Power Institute of China, Chengdu (CN)

(72) Inventors: Yanping HUANG, Chengdu (CN); Yaoxing CHEN, Chengdu (CN); Lv YE, Chengdu (CN); Le MA, Chengdu (CN); Xiuting LIU, Chengdu (CN); Houjun GONG, Chengdu (CN); Wenbin ZHUO, Chengdu (CN); Yu JIANG, Chengdu (CN); Bitan QIN, Chengdu (CN); Liqin ZHANG, Chengdu (CN)

(73) Assignee: Nuclear Power Institute of China, Chengdu (CN)

(21) Appl. No.: 19/433,659

(22) Filed: Dec. 26, 2025

Related U.S. Application Data
(63) Continuation of application No. PCT/CN2024/124447, filed on Oct. 12, 2024.

(30) Foreign Application Priority Data
Jul. 22, 2024 (CN) 202410981195.6

(51) Int. Cl. G06F 30/28

(52) U.S. Cl. CPC G06F 30/28

(57) ABSTRACT

A design method for a supercritical carbon dioxide compressor includes: obtaining a performance curve of the supercritical carbon dioxide compressor based on the fluid similarity theory; performing off-design performance correction of the supercritical carbon dioxide compressor based on the performance curve; controlling a dry gas seal temperature of the supercritical carbon dioxide compressor based on a correspondence between temperature and pressure; and providing a fluid dynamic pressure gap between a high-speed shaft gear and a low-speed shaft gear in a gearbox of the supercritical carbon dioxide compressor, and adjusting a gearbox thrust through the fluid dynamic pressure gap.

### CROSS-REFERENCE TO RELATED APPLICATIONS

The present application is a continuation application of International Application No. PCT/CN2024/124447, filed on Oct. 12, 2024, which claims priority to Chinese Patent Application No. 202410981195.6, filed with the China National Intellectual Property Administration on Jul. 22, 2024. All of the aforementioned applications are incorporated herein by reference in their entireties.

### TECHNICAL FIELD

The present application relates to the technical field of turbomachinery, and in particular to a design method for a supercritical carbon dioxide compressor.

### BACKGROUND

The supercritical carbon dioxide thermodynamic cycle power generation technology is an emerging generalized power solution that leverages the unique physical properties of supercritical carbon dioxide as the working fluid, and achieves integrated matching of working fluid properties, cycle processes, and equipment innovations based on the principles of the Brayton cycle. This technology holds promise for rapid deployment in fields such as nuclear energy, solar thermal power, gas-fired power plants, waste heat recovery, and biomass power generation. It is expected to drive technological and industrial transformation in these areas, while also promoting the development of equipment manufacturing in the energy sector.

As a core component of the supercritical carbon dioxide power conversion system, the compressor is responsible for providing the circulating power required by the system. The working fluid at the inlet of the supercritical carbon dioxide compressor is characterized by high density, which can effectively reduce the compressor's power consumption and thereby improve the cycle efficiency of the power conversion system. This makes the design of supercritical carbon dioxide turbomachinery a key area of focus for many research institutions. The high-density property of supercritical carbon dioxide results in compressor designs that feature compact size and high rotational speed, which in turn presents the following challenges in compressor design.

The inlet temperature of the supercritical carbon dioxide compressor is usually very close to the critical point (7.38 MPa, 31.1° C.). However, the thermophysical properties of carbon dioxide undergo rapid changes near the critical point, resulting in large property interpolation errors and insufficient cavitation margin, which in turn makes compressor design challenging.

Under actual operating conditions, the inlet temperature and the pressure of the compressor need to fluctuate within a certain range and deviate from the design operating condition point. However, the sharply varying thermophysical properties near the critical point can cause the inlet fluid density to deviate from the design value, thereby requiring off-design aerodynamic performance verification of the compressor. Performing numerical simulation and validation for each newly established combination of fluid temperature and pressure would result in a tremendous workload, making it difficult to meet the demands of rapid performance verification during system operation or simulation.

The existing supercritical carbon dioxide compressors usually adopt dry gas seals and use bleed gas extracted from the main gas system, of which the compressor is a part, as the source of sealing gas. Since the pressure of the carbon dioxide working fluid in the main gas system generally ranges from 6 to 20 MPa, while the outlet pressure of the sealing gas is only slightly above atmospheric pressure, the large pressure differential can result in significant temperature changes in the carbon dioxide gas flow. Therefore, it is necessary to effectively regulate the outlet temperature of the sealing gas to ensure the stable operation of the dry gas seal.

The gearbox of the supercritical carbon dioxide compressor needs to continuously operate at a high speed, resulting in significant bearing losses within the gearbox. This not only restricts the output power of the system, but also affects the effective operation of the system.

In view of this, based on years of experience in production design in this field and related areas, has developed a design method for a supercritical carbon dioxide compressor through repeated experiments, aiming to solve the existing problems.

### SUMMARY

The purpose of the present application is to provide a design method for a supercritical carbon dioxide compressor, which can effectively meet the design requirements of small volume and high rotating speed of the supercritical carbon dioxide compressor.

In order to achieve the above purpose, the present application provides a design method of a supercritical carbon dioxide compressor. The design method includes: obtaining a performance curve of the supercritical carbon dioxide compressor based on the fluid similarity theory; performing off-design performance correction of the supercritical carbon dioxide compressor based on the performance curve; controlling a dry gas seal temperature of the supercritical carbon dioxide compressor based on a correspondence between temperature and pressure; and providing a fluid dynamic pressure gap between a high-speed shaft gear and a low-speed shaft gear in a gearbox of the supercritical carbon dioxide compressor, and adjusting a gearbox thrust through the fluid dynamic pressure gap.

Compared with the prior art, the present application has the following features and advantages.

According to the design method of the supercritical carbon dioxide compressor provided in the present application, the thermophysical property range of the supercritical carbon dioxide is equated to that of an ideal working medium. Since the thermophysical properties of the ideal working fluid do not undergo sharp changes during the thermodynamic cycle, the issue of abrupt property changes in the critical region of carbon dioxide is avoided. The compressor design is then carried out based on the equivalent ideal working fluid for both the rated and off-design conditions. Finally, the performance curve of the compressor using the equivalent ideal working fluid is scaled back to the performance curve of the supercritical carbon dioxide compressor based on the fluid similarity theory. This method addresses the issue of inaccurate property interpolation and the difficulties in designing supercritical carbon dioxide compressors due to the sharp property changes near the critical region of carbon dioxide, providing technical support and guidance for the design of supercritical carbon dioxide compressors and high-efficiency supercritical carbon dioxide cycles.

The design method of the supercritical carbon dioxide compressor in this application performs off-design aerodynamic performance correction based on the performance curve under the design conditions. This method allows for the rapid acquisition of the performance curve of the supercritical carbon dioxide compressor under off-design conditions. With the performance curve under off-design conditions, the compressor performance at off-design conditions can be quickly and accurately calculated. This not only simplifies calculation workload for the off-design performance, greatly saving calculation time and resources, but also meets the need for rapid iteration of the compressor design.

The design method of the supercritical carbon dioxide compressor proposed in this application imposes restrictions on the relationship between temperature and pressure of the injected gas flow for the dry gas seal to ensure that the temperature of the leakage gas flow from the dry gas seal is close to the oil inlet temperature of the bearing in the gearbox, thereby ensuring the safe operation of the bearing.

The design method of the supercritical carbon dioxide compressor proposed in the present application sets a fluid dynamic pressure gap between the high-speed shaft gear and the low-speed shaft gear in the gearbox. The thrust of the high-speed shaft gear is transmitted to the low-speed shaft gear through the fluid dynamic pressure gap, and then the thrust of the low-speed shaft gear is balanced, which can significantly improve the efficiency of the gearbox and the overall output power of the compressor unit.

### BRIEF DESCRIPTION OF THE DRAWINGS

The drawings described herein are for explanation purposes only and are not intended to limit the scope of the present application in any way. In addition, the shapes, proportions, sizes, and the like of the components in the drawings are merely illustrative and are used to help understand the present application, and are not intended to specifically limit the shapes and proportions of the components of the present application. Those skilled in the art can select various possible shapes and proportions to implement the present application according to specific circumstances under the teachings of the present application.

FIG. 1 is a schematic diagram of supercritical carbon dioxide cycle in the present application.

FIG. 2 is a schematic diagram of an off-design condition correction method based on compressor performance curve verification according to the present application.

FIG. 3 is a graph of a performance curve of pressure ratio of the supercritical carbon dioxide compressor under a design condition.

FIG. 4 is a graph of performance curve of efficiency of the supercritical carbon dioxide compressor under design conditions.

FIG. 5 is a graph of a performance curve of pressure ratio of the supercritical carbon dioxide compressor under an off-design condition.

FIG. 6 is a graph of a performance curve of efficiency of the supercritical carbon dioxide compressor under the off-design condition.

FIG. 7 is an arrangement diagram of a dry gas sealing device according to the present application.

FIG. 8 is a partial enlarged view of the dry gas sealing device according to the present application.

FIG. 9 is a schematic diagram of a thrust transmission structure of a gearbox according to the present application.

FIG. 10 is a partial enlarged view of a thrust transmission structure of a gearbox according to the present application.

FIG. 11 is a partial enlarged view of a thrust transmission wedge surface of the gearbox according to the present application.

FIG. 12 is a partial enlarged view of the thrust transmission wedge surface of the gearbox according to the present application.

FIG. 13 is a schematic diagram of a thrust balance structure of the gearbox according to the present application.

### DETAILED DESCRIPTION OF THE EMBODIMENTS

The details of the present application can be understood more clearly in combination with the accompanying drawings and the description of specific implementations of the present application. However, the specific embodiments of the present application described herein are only used for explaining the purpose of the present application, and cannot be understood in any way as a limitation to the present application. In light of the teachings of the present application, a person skilled in the art may conceive of any possible modifications based on the present application, all of which should be considered as falling within the scope of the present application.

The present application provides a design method for a supercritical carbon dioxide compressor, the design method including: obtaining a performance curve of the supercritical carbon dioxide compressor based on the fluid similarity theory; performing off-design performance correction of the supercritical carbon dioxide compressor based on the performance curve; controlling dry gas seal temperature of the supercritical carbon dioxide compressor based on the correspondence between temperature and pressure; and setting a fluid dynamic pressure gap between a high-speed shaft gear and a low-speed shaft gear in a gearbox of the supercritical carbon dioxide compressor, and adjusting a gearbox thrust through the fluid dynamic pressure gap.

According to the design method of the supercritical carbon dioxide compressor provided in the present application, the thermophysical property range of the supercritical carbon dioxide is equated to that of an ideal working medium. Since the thermophysical properties of the ideal working fluid do not undergo sharp changes during the thermodynamic cycle, the issue of abrupt property changes in the critical region of carbon dioxide is avoided. The compressor design is then carried out based on the equivalent ideal working fluid for both the rated and off-design conditions. Finally, the performance curve of the compressor using the equivalent ideal working fluid is scaled back to the performance curve of the supercritical carbon dioxide compressor based on the fluid similarity theory. This method addresses the issue of inaccurate property interpolation and the difficulties in designing supercritical carbon dioxide compressors due to the sharp property changes near the critical region of carbon dioxide, providing technical support and guidance for the design of supercritical carbon dioxide compressors and high-efficiency supercritical carbon dioxide cycles.

The design method of the supercritical carbon dioxide compressor in the present application performs off-design aerodynamic performance correction based on the performance curve under the design conditions. This method allows for the rapid acquisition of the performance curve of the supercritical carbon dioxide compressor under off-design conditions. With the performance curve under off-design conditions, the compressor performance at off-design conditions can be quickly and accurately calculated. This not only simplifies calculation workload for the off-design performance, greatly saving calculation time and resources, but also meets the need for rapid iteration of the compressor design.

The design method of the supercritical carbon dioxide compressor proposed in the present application imposes restrictions on the relationship between temperature and pressure of the injected gas flow for the dry gas seal to ensure that the temperature of the leakage gas flow from the dry gas seal is close to the oil inlet temperature of the bearing in the gearbox, thereby ensuring the safe operation of the bearing.

The design method of the supercritical carbon dioxide compressor proposed in the present application sets a fluid dynamic pressure gap between the high-speed shaft gear and the low-speed shaft gear in the gearbox. The thrust of the high-speed shaft gear is transmitted to the low-speed shaft gear through the fluid dynamic pressure gap, and then the thrust of the low-speed shaft gear is balanced, which can significantly improve the efficiency of the gearbox and the overall output power of the compressor unit.

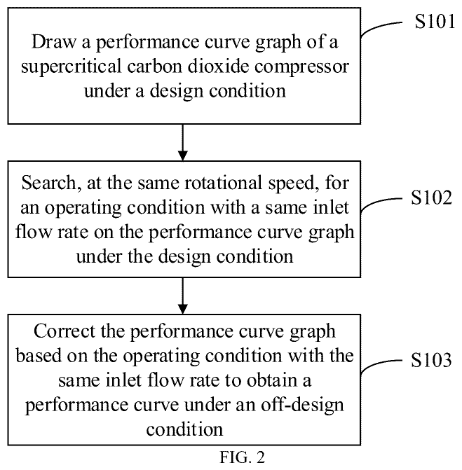

In an implementation of the present application, as shown in FIG. 2, the design method for the supercritical carbon dioxide compressor is based on the fluid similarity theory, in which the property ranges of supercritical carbon dioxide are equivalently mapped to the corresponding property ranges of an ideal working fluid. The compressor is designed for both rated and off-design conditions using the ideal working fluid, and the performance curves of the compressor for the ideal working fluid are obtained. Based on fluid similarity theory, the performance curves of the compressor for the ideal working fluid are then scaled back to obtain the performance curves of the supercritical carbon dioxide compressor.

In an embodiment, at the inlet of the supercritical carbon dioxide centrifuge, the carbon dioxide is in a supercooled liquid state; and at the outlet of the supercritical carbon dioxide centrifuge, the carbon dioxide is in a supercritical state.

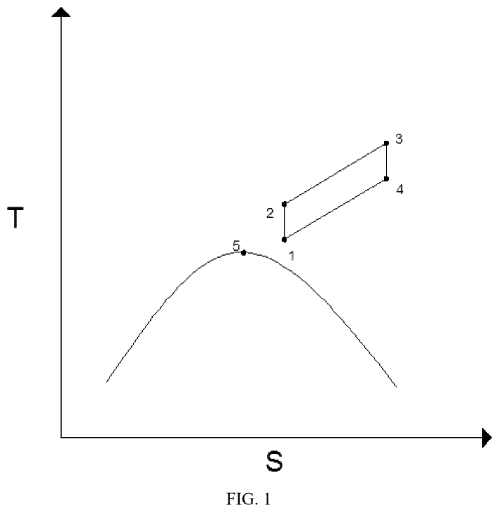

As shown in FIG. 1, the supercritical carbon dioxide cycle refers to a cycle in which the temperature and pressure of carbon dioxide at the compressor inlet (i.e., at point 1 in FIG. 1) are lower than the critical point (i.e., at point 5 in FIG. 1). Compared with a typical supercritical carbon dioxide cycle, reducing the inlet temperature of the compressor in this configuration is beneficial for improving cycle efficiency, thereby increasing overall system power output. This improvement in efficiency offers considerable economic benefits.

It should be noted that the critical point corresponds to a pressure of 7.38 Pa and a temperature of 31.1° C.

In an implementation of the present application, the performance index of the supercritical carbon dioxide includes a pressure ratio, a mass flow rate, and an isentropic efficiency.

Based on the fluid similarity theory, the pressure ratio and the mass flow rate of the supercritical carbon dioxide are equivalent to the corresponding physical property ranges of an ideal working medium, and the ideal working medium may be one or more.

In an embodiment of the present embodiment, the fluid similarity theory includes a Reynolds number similarity, a Planck number similarity, a geometric similarity, and an empirical approximation relationship.

In an embodiment of the present application, the operating condition design includes calculating various parameters of the compressor, and specifically includes: the head coefficient and specific speed of the compressor, the inlet diameter of the compressor, the outlet speed of the impeller of the compressor, and the diameter of the outlet of the impeller of the compressor.

Specifically, the Reynolds number is a basic similarity criterion that ensures similar fluid flow characteristics, and is defined as follows:

$${Re}_{D} = \frac{ρ VD}{μ} \qquad ( 1 )$$

where ρ is the fluid density; V is the fluid velocity; D) is the inlet diameter of the compressor; μ is the dynamic viscosity coefficient; Re_{D} is the Reynolds number.

In the supercritical region of carbon dioxide, thermophysical properties such as the specific heat capacity at constant pressure vary sharply. Therefore, the Prandtl number, which characterizes the heat transfer capability of a fluid, is employed as one of the similarity criteria. The Prandtl number is defined as follows:

$$P r = v / a \qquad ( 2 )$$

In the equation, ν is the kinematic viscosity, α is the thermal diffusivity, and Pr is the Prandtl number.

Further, Prandtl number similarity requires that the head coefficient and specific speed of the compressor be equal. These parameters are defined as follows:

$$H = \frac{{zRT}_{t , in}}{κ - 1 / κ} ( {π}_{c}^{κ - 1 / κ} - 1 ) \qquad ( 3 )$$

$${n}_{s} = \frac{ω \sqrt{Q}}{{( H )}^{0.75}} \qquad ( 4 )$$

In the equation, H is the head coefficient of the compressor; z is the average compression coefficient between the inlet and outlet of the compressor; R is the specific gas constant of carbon dioxide; T_{t,in} is the inlet total temperature at the inlet; κ is the specific heat ratio; π_{c} is pressure ratio between the inlet and the outlet; ω is the angular speed of the rotor; Q is the volumetric flow rate at the inlet; and nₛ is the specific speed.

The geometric similarity is ensured by maintaining equal flow coefficient, volumetric flow rate, and rotational speed. The flow coefficient is defined as follows:

$$φ = \frac{Q}{{V}_{2} {D}_{2}^{2}} \qquad ( 5 )$$

In the equation, V₂ is the outlet speed of the compressor impeller, D₂ is the outlet diameter of the compressor impeller, Q is the volumetric flow rate at the inlet, and φ is the flow coefficient.

In the present embodiment, the compressor design method for each equivalent ideal working fluid adopts the 2D mean-line approach. This method utilizes compressor speed triangles under various loss models to predict off-design performance behavior.

In an implementation of the present application, the performance curve of the ideal working fluid is scaled back to the performance curve of supercritical carbon dioxide. This scaling process includes converting the pressure ratio of the supercritical carbon dioxide based on Prandtl number similarity and equal isentropic head coefficient. Specifically, the pressure ratio of the supercritical carbon dioxide compressor is obtained under the condition of equal isentropic head coefficient, as follows:

$${π}_{c} = ( 1 + \frac{{z}_{ideal} {κ}_{ideal} {R}_{ideal} {T}_{ideal}}{{z}_{CO 2} {κ}_{CO 2} {R}_{CO 2} {T}_{CO 2}} \frac{{κ}_{ideal} - 1}{{κ}_{CO 2}} ( {π}_{c}^{* ( {κ}_{\text{?}} - 1 ) / {κ}_{\text{?}}} - 1 ) ) . \qquad ( 6 )$$

$$\text{?} \text{indicates text missing or illegible when filed}$$

In the equation, π_{C} is the pressure ratio of the supercritical carbon dioxide compressor; Z_{ideal}, K_{ideal}, D_{ideal}, and T_{ideal} π_{C}* are the average compressibility factor between the inlet and outlet, the specific gas constant, the total inlet temperature, the specific heat ratio, and the pressure ratio respectively, of the equivalent ideal working fluid; Z_{co2}, K_{co2}, D_{co2}, T_{co2} are the average compressibility factor, the specific gas constant, the total inlet temperature, and the specific heat ratio, respectively, of carbon dioxide.

The mass flow rate of the supercritical carbon dioxide is converted according to the geometric similarity. The converted mass flow rate of the supercritical carbon dioxide is as follows:

$${m}_{CO 2} = \frac{{ρ}_{CO 2}}{{ρ}_{ideal}} {m}_{ideal} \qquad ( 7 )$$

In the equation, ρ_{co2}, ρ_{ideal}, m_{ideal} are the density of carbon dioxide, the density of the equivalent ideal working fluid, and the mass flow rate of the equivalent ideal working fluid, respectively; and m_{co2} is the mass flow of the supercritical carbon dioxide compressor.

The isentropic efficiency of the supercritical carbon dioxide is obtained by scaling according to the approximate empirical relationship, and the empirical relationship, which is expressed as follows:

$${η}_{CO 2} \approx 1 - ( 1 - {η}_{ideal} ) {( \frac{{D}_{2 , ideal}}{{D}_{2 , CO 2}} )}^{n} \qquad ( 8 )$$

where η_{co2} is the expansion index of carbon dioxide, η_{ideal} is the expansion index of the equivalent ideal working fluid, D_{2,ideal} is the total outlet temperature of the compressor for the ideal working fluid, and D_{2,co2} is the total outlet temperature of the compressor for carbon dioxide.

At the rated operating condition, the diameter ratio of the outlet of the impeller is solved as follows:

$${( \frac{{h}_{\text{?}} ( {π}_{\text{?}}^{\text{?}} - 1 )}{ε} )}_{CO 2} = \frac{{D}_{2 , ideal}}{{D}_{2 , CO 2}} {( \frac{{h}_{\text{?}} {π}_{\text{?}}^{\text{?}} - 1}{ε} )}_{ideal} \qquad ( 9 )$$

$$\text{?} \text{indicates text missing or illegible when filed}$$

In the equation, hₜ₁ is the total enthalpy at the inlet, E is the slip factor, D_{2,ideal} is the total outlet temperature of the compressor for the equivalent ideal working fluid, D_{2,co2} is the total outlet temperature of the compressor for carbon dioxide, π_{C} is the pressure ratio of the supercritical carbon dioxide compressor, and κ is the specific heat ratio.

Therefore, the expansion index n can be obtained according to the impeller outlet diameter ratio at the rated operating condition and equation (7), which then allows the complete empirical correlation for isentropic efficiency to be obtained.

In an implementation of the present application, as shown in FIG. 2, the off-design performance correction of the supercritical carbon dioxide compressor based on the compressor performance curve includes the follow steps:
S101, drawing a performance curve of a supercritical carbon dioxide compressor under a design condition;
S102, searching, at the same rotational speed, for an operating condition with a same inlet flow rate on the performance curve graph under the design condition; and
S103, correcting the performance curve graph based on the operating condition with the same inlet flow rate to obtain a performance curve under an off-design condition.

The method for correcting the off-design operating conditions of the performance curve for the supercritical carbon dioxide compressor proposed in this application is based on modifying the aerodynamic performance curve at off-design operating conditions from the performance curve under design conditions. By using a single off-design calculation simulation, the entire off-design performance curve is obtained. This significantly reduces calculation time and workload, making it capable of meeting the system's need for rapid, high-frequency iterations during operation or simulation.

In the present application, off-design conditions refer to deviations in the temperature and pressure at the inlet of the supercritical carbon dioxide compressor from the design values. When the inlet temperature or pressure of the supercritical carbon dioxide compressor deviates from the design values, the performance curve of the compressor changes significantly. It is necessary to recalculate the performance curve of the supercritical carbon dioxide compressor to accurately predict its actual performance, such as pressure-boosting capacity, work efficiency, and other related parameters.

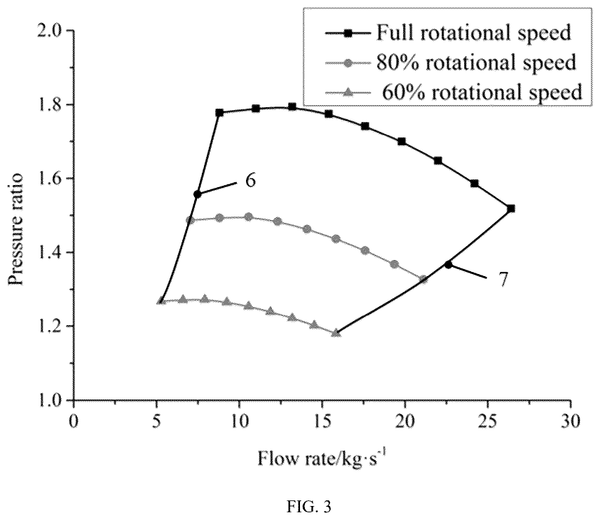

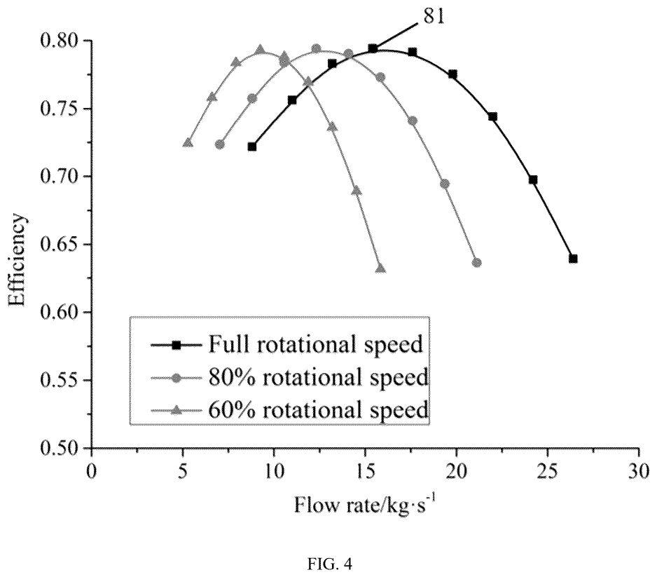

In an implementation, as shown in FIG. 3 and FIG. 4, the performance curve graph at least includes a total static pressure ratio performance curve graph and a total static isentropic efficiency performance curve graph.

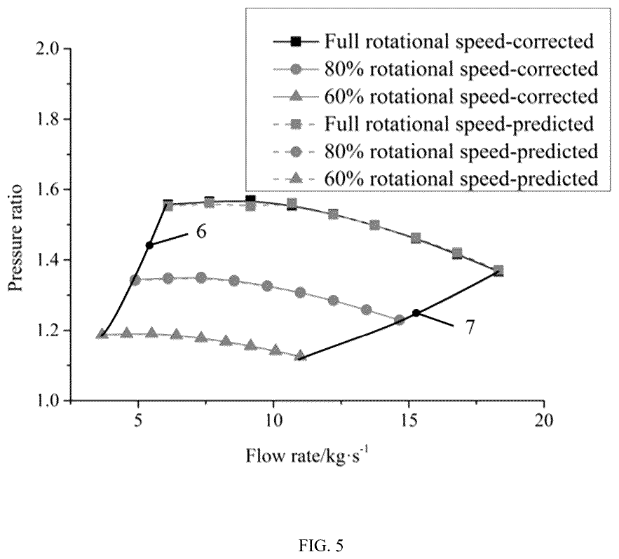

In an embodiment of the present embodiment, as shown in FIG. 5, the total static pressure ratio performance curve is modified to obtain the off-design total static pressure ratio performance curve (as shown in FIG. 5) by applying the principle of constant enthalpy rise at the same inlet flow rate.

Specifically, taking the design operating point with full rotational speed and a mass flow rate of 22 kg/s as an example, when the inlet temperature of the compressor increases by 2° C. while the pressure remains unchanged, the inlet density decreases to 69.4% of that under the original design condition. As the mass flow rate for the compressor is proportional to the product of density, flow velocity, and inlet area, under the conditions where the flow speed remains unchanged and the inlet geometric area is constant, the decrease in density leads to a reduced mass flow rate at the same flow velocity, specifically satisfying the following:

$${m}_{x} = \frac{{ρ}_{x}}{{ρ}_{o}} {m}_{o} \qquad ( 10 )$$

where mₓ is the corrected mass flow rate under the same rotational speed and flow speed; ρₓ is the inlet density of the compressor under the off-design condition; ρₒ is the inlet density of the compressor under the original design condition, and mₒ is the mass flow rate of the compressor under the original design condition.

Under the design condition, the actual work done by the compressor corresponds to the increase in enthalpy. However, since the change in outlet pressure of the compressor is independent of the change in entropy, the outlet pressure of the compressor can be calculated based on isentropic enthalpy, as follows:

$$h = {h}_{inlet} - Δ h \qquad ( 11 )$$

In the equation, h is an isentropic enthalpy at the compressor outlet under any operating condition, hᵢₙₗₑₜ is an enthalpy at the compressor inlet, and Δh is the isentropic enthalpy rise of the compressor.

Therefore, when the enthalpy remains unchanged at the same flow velocity, the isentropic work capacity of the compressor under the off-design condition is corrected as follows:

$${h}^{′} = {h}_{inlet}^{′} + Δ h \qquad ( 12 )$$

In the equation, h′ is an isentropic enthalpy at the compressor outlet at any point under the off-design condition, hᵢₙₗₑₜ′ is an enthalpy at the compressor inlet under the off-design condition, and Δh is the isentropic enthalpy rise of the compressor, which remains unchanged.

According to the isentropic enthalpy obtained through recalculation, the static pressure at the compressor outlet under off-design conditions can be obtained by referencing a supercritical carbon dioxide property database. Then, the ratio of the static pressure at the compressor outlet to the total pressure at the compressor inlet under off-design conditions is the total-to-static pressure ratio under off-design conditions.

In fact, the corrected total-to-static pressure ratio is highly consistent with the recalculated total-to-static pressure ratio. This is because, for a supercritical carbon dioxide compressor, the energy process during impeller work satisfies the following equation:

$$Δ h = {C}_{2 u} {U}_{2} - {C}_{1 n} {U}_{1} \qquad ( 13 )$$

In the equation, C₂ᵤ, C₁ᵤ, are the circumferential speeds of the airflow at the impeller outlet and inlet, respectively; U₂, U₁ are the peripheral speeds at the outlet and inlet, respectively; and Δh is the isentropic enthalpy rise of the compressor.

For the compressor with axial inlet, the axial speed of the inlet airflow is 0, so the above equation can be further simplified as follows:

$$Δ h = {C}_{2 n} {U}_{2} \qquad ( 14 )$$

In the equation, C₂ᵤ is the circumferential speed of the airflow at the impeller outlet; and U₂ is the peripheral speed at the outlet; and Δh is the isentropic enthalpy rise of the compressor.

Further, for the compressor, most of the airflow at the impeller outlet has only the circumferential speed, and the radial speed accounts for a very small proportion. Therefore, in simplified calculations, C₂ᵤ can be approximated as U₂. Thus, the equation can be further simplified as follows:

$$Δ h \approx {U}_{2}^{2} \approx {( ω {R}_{2} )}^{2} \qquad ( 15 )$$

In the equation, ω is an angular speed, R₂ is an impeller outlet radius, U₂ is an outlet circumferential speed, and Δh is the isentropic enthalpy rise of the compressor which remains unchanged.

Therefore, based on the above, it can be found that when the rotational speed and the impeller geometric parameter remain unchanged, the work capability of the compressor essentially remains unchanged. This is the reason why, in this embodiment, the pressure ratio correction is performed by maintaining a constant enthalpy rise, which results in favorable outcomes.

In an embodiment, the surge line 6 and the chock line 7 are established according to the total-to-static pressure ratio performance curve under the design condition, based on the principle of maintaining constant inlet flow speed at the same rotational speed.

The surge line and the chock line are important boundaries and evaluation indexes for safe operation of the compressor. The surge line represents the minimum flow operation boundary of the compressor, while the choke line represents the maximum flow operation boundary of the compressor. When the inlet temperature or pressure of the compressor deviates from the design condition, the surge line and the chock line need to be recalculated according to the following equation:

$${m}_{x} = \frac{{ρ}_{x}}{{ρ}_{0}} {m}_{o} \qquad ( 16 )$$

In the equation, mₓ is the corrected flow rate under the off-design condition; ρₓ is the inlet density of the compressor under the off-design condition; ρₒ is the inlet density of the compressor under the original design condition, and mₒ is the choke or surge flow rate of the compressor under the original design condition.

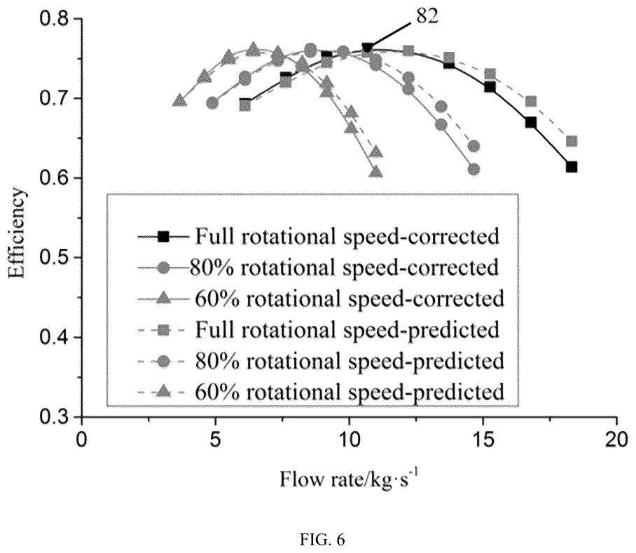

In an implementation of the present application, the total-to-static isentropic efficiency performance curve is overall corrected based on the total-static isentropic efficiency correction factor to obtain the total-to-static isentropic efficiency performance curve under off-design condition (as shown in FIG. 6). Then, by a single correction, the efficiency-flow performance relationship curve for all rotational speeds, including full speed, 80% speed, and 60% speed, can be obtained, greatly simplifying the calculation workload.

In this embodiment, the principle of overall correction is proposed based on the assumption that the compressor speed triangle remains unchanged (i.e., constant inlet flow speed, constant impeller axial speed, and constant geometric structure). Therefore, the work capacity of the impeller remains unchanged. When the compressor inlet temperature increases, the pressure-boosting capacity decreases, resulting in a reduction in density. This leads to lower friction losses under off-design conditions at high flow rates compared to the design condition. As a result, an increase in compressor inlet temperature will cause the predicted value at high flow conditions to be slightly higher than the corrected value. However, overall, in this embodiment, the correction efficiency for off-design conditions has a deviation from the predicted efficiency of no more than 3%, which is sufficient to meet the requirements for rapid prediction.

In an example of this implementation, the calculation for the total-to-static isentropic efficiency overall correction factor is as follows.

As shown in FIG. 4, the design flow rate and the design rotational speed corresponding to the maximum total-to-static isentropic efficiency point 81 at the rated speed on the total-to-static isentropic efficiency performance curve under the design condition are obtained.

As shown in FIG. 6, according to the principle of equal inlet flow speed, the corresponding off-design condition reference flow point 82 for the maximum total-to-static isentropic efficiency under the design condition is found, and the total-to-static isentropic efficiency at this reference flow point is calculated.

The total-to-static isentropic efficiency overall correction factor is calculated the total-to-static isentropic efficiency at the reference flow point and the maximum total-to-static isentropic efficiency under the design condition.

In an embodiment, the reference flow point 82 under the off-design condition is found by applying the equal inlet flow speed principle to the design flow rate at the maximum total-to-static isentropic efficiency point 81 at the rated speed.

In an embodiment, according to the inlet pressure and the temperature under the off-design condition, as well as the flow rate and converted rotational speed at the reference flow point, simulation calculation is performed to obtain the converted total-to-static isentropic efficiency.

In an embodiment, the design rotational speed is converted into the converted rotational speed at the reference flow point under the off-design condition, according to the principle of constant rotational speed.

In an embodiment, the total-to-static isentropic efficiency overall correction factor is the ratio of the total-to-static isentropic efficiency at the reference flow point to the maximum total-to-static isentropic efficiency under the design condition.

In an embodiment of the present application, the dry gas seal temperature of the supercritical carbon dioxide compressor is controlled based on the corresponding relationship between temperature and pressure, as follows.

The dry gas seal device, which implements the dry gas sealing, is suspended on the gearbox of the supercritical carbon dioxide compressor, and an injection gas flow is introduced into the dry gas seal device.

The relationship between the pressure and the temperature of the injection gas flow is as follows.

$${T}_{min} = - 0.0032 {P}^{3} + 0.0041 {P}^{2} + 6.0759 P + 42.262 \qquad ( 17 )$$

$${T}_{max} = 0.0118 {P}^{3} - 0.5304 {P}^{2} + 11.581 P + 48.113 \qquad ( 18 )$$

where Tₘᵢₙ is the lowest temperature of the introduced injection gas flow; Tₘₐₓ is the highest temperature of the introduced injection gas flow; and P is the pressure of the introduced injection gas flow.

In this embodiment, the temperature of the dry gas seal leakage gas is regulated based on the constraint relationship between the temperature and pressure of the total inlet gas flow of the dry gas seal device, ensuring that the temperature deviation between the dry gas seal leakage gas and the oil temperature at the bearing inlet is controlled within ±0.4° C., so as to ensure the operation safety of bearing.

In an embodiment, the gas flow pressure of the injection gas flow is applicable in a range of 6 MPa to 20 MPa.

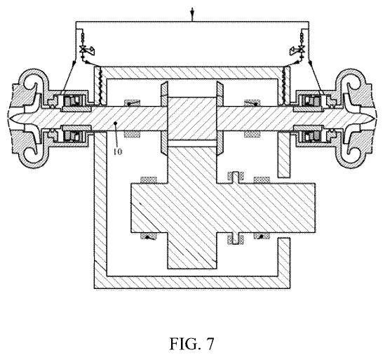

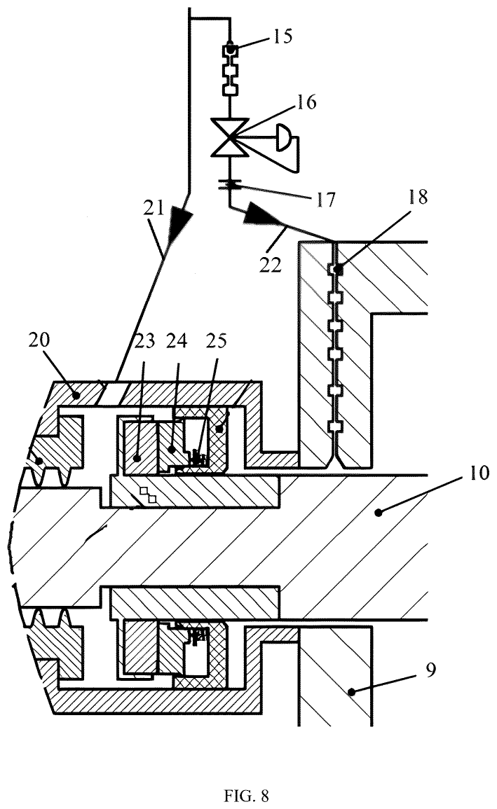

In an implementation, after introduced into the dry gas seal device, the injection gas flow is divided into a main gas flow 21 and an isolation gas flow 22. As shown in FIG. 7 and FIG. 8, specifically, the main gas flow 21 is used to enter the seal housing of the dry gas seal device, so as to form a rigid gas film between the rotating ring and the stationary ring; the isolation gas flow 22 runs in parallel with the main gas flow 21 and is used to enter the gearbox to provide oil-gas isolation. By limiting the relationship between the temperature and the pressure of the total gas flow upstream of the split between the dry gas seal main gas flow 21 and the isolation gas flow 22, it is ensured that the outlet temperatures of both the dry gas seal leakage gas flow and the isolation gas flow 22 are close to the oil temperature at the bearing inlet, so that the oil inlet temperature of the oil-lubricated bearing in the downstream gearbox can be maintained within the operational range, thereby ensuring the safe operation of the bearing.

In an embodiment, when the outlet temperature of the dry gas seal leakage gas flow and the isolation gas flow 22 is elevated to a maximum of 62° C., the maximum temperature of the total inlet gas flow to the dry gas seal device does not exceed 162° C. under a pressure condition of 20 MPa. When the outlet temperature of the dry gas seal leakage gas flow and the isolation gas flow 22 drops to a minimum of 20° C., the minimum temperature of the total inlet gas flow to the dry gas seal device is not lower than 139° C. under a pressure condition of 20 MPa.

In an embodiment, the gas seal device includes a sealing cylinder 20, and a moving ring 23 and a static ring 24 arranged inside the sealing cylinder 20. It can be seen from the prior art that the side of the static ring 24 that is away from the moving ring 23 is typically provided with a spring 25 to apply an adhesion force, ensuring a tight contact between the moving and static rings in the stationary condition. During the operation of the dry gas seal, the moving ring 23 and the static ring 24 cooperate with each other, and the injection gas flow can form a rigid gas film between the moving ring 23 and the static ring 24. When the static pressure of the fluid and the closing force from the spring 25 equal the opening force generated by the gas film, a stable gap is formed between the radial faces.

In an implementation, a flow resistance member 15, a pressure relief valve 16, and a throttling hole 17 are sequentially arranged along the flow direction of the isolation gas flow 22. The isolation gas flow 22 is depressurized step by step through the flow resistance member 15, the pressure relief valve 16, and the throttling hole 17, in order to meet the requirements of a large pressure drop in the isolation gas flow 22 and to prevent frosting at the throat of the pressure relief valve 16. This provides support for the design and safe operation of the supercritical carbon dioxide compressor or turbine.

In an embodiment, the pressure drop distribution principle for the isolation gas flow 22 is that the minimum isentropic expansion temperature at the throat of the pressure relief valve 16 is higher than zero degrees Celsius, further ensuring that the throat of the pressure relief valve 16 does not frost. When the temperature at the throat of the pressure relief valve 16 drops below zero degrees Celsius, moisture from the external air working fluid may frost on the valve stem surface, potentially causing the pressure relief valve 16 to seize and making automatic control difficult. Therefore, this situation needs to be avoided. A sudden expansion phenomenon occurs at the throat of the pressure relief valve 16, and the temperature at this point is considered under isentropic conditions. To avoid the supercritical carbon dioxide's temperature dropping below zero degrees Celsius under large pressure drop isentropic expansion conditions, the pressure difference before and after the pressure relief valve 16 needs to be limited. It is recommended that the pressure difference not exceed 9 to 11 MPa, with the remaining pressure drop being handled by the flow resistance member 15 upstream of the pressure relief valve 16 and the throttling hole 17 downstream of the pressure relief valve 16.

In an embodiment, a pressure regulation groove 18 is also arranged on the branch flow path of the isolation gas. The isolation gas flows sequentially through the flow resistance member 15, the pressure relief valve 16, the throttling hole 17, and the pressure regulation groove 18 before entering the downstream of the moving ring 23 and static ring 24 of the dry gas seal device for oil-gas isolation.

In an embodiment, the pressure regulation groove 18 is arranged on the gearbox housing, which makes full use of the wall thickness advantage of the gearbox housing to reduce the axial length of the shaft, increase the rotor's critical speed, and thereby help increase the margin for avoiding the critical speed during operation and reduce vibration amplitude.

In an embodiment, the gas flow pressure downstream of the moving ring 23 and static ring 24 of the dry gas seal device ranges from 0.11 MPa(a) to 0.15 MPa(a). According to the design specifications, the exit flow speed of the isolation gas must meet the requirement of being no less than 5 m/s to effectively prevent reverse oil-gas flow. Considering that the source of the isolation gas comes from the main circuit system of the compressor or turbine, to reduce the power loss caused by the isolation gas, the amount of isolation gas used should be kept as low as possible. Under the condition of fixed geometric dimensions, lowering the pressure to control the gas flow density of the isolation gas can effectively increase the flow velocity, thus improving the performance. On the other hand, excessively high oil pressure in the bearings of the downstream gearbox can lead to increased power consumption of the oil routing system, increased bearing wear losses, and possibly cause the lubrication oil to splash out of the bearing. After comprehensive consideration, the downstream gas flow pressure is selected to be 0.11 MPa(a) to 0.15 MPa(a).

In an embodiment, the total mass of the leakage gas flow and isolation gas flow 22 downstream of the moving ring 23 and static ring 24 of the dry gas seal device is not higher than 5% of the bearing oil inlet mass. Specifically, the oil temperature at the bearing inlet can cause the viscosity of the lubricant to become too high, leading to increased losses in the unit, excessive bearing temperature rise, which may trigger an alarm and shutdown. The oil temperature at the bearing inlet can also cause oil oxidation and degradation, leading to bearing failure incidents. Typically, it is recommended to control the oil temperature at the bearing inlet in the range of 36 to 46° C. Since, in a zero-leakage scenario, the dry gas seal leakage gas and isolation gas directly flow through the bearing, excessive leakage gas mass can make the bearing oil temperature more susceptible to fluctuations in gas flow temperature. Therefore, to reduce the sensitivity of the bearing oil temperature to gas flow temperature, based on existing design experience, it is required that the total mass of the leakage gas and isolation gas should not exceed 5% of the bearing oil inlet mass. Under these design conditions, a 4° C. deviation in the dry gas seal and isolation gas outlet temperature would only cause a 0.1° C. deviation in the oil temperature at the bearing inlet, significantly improving operational safety and convenience.

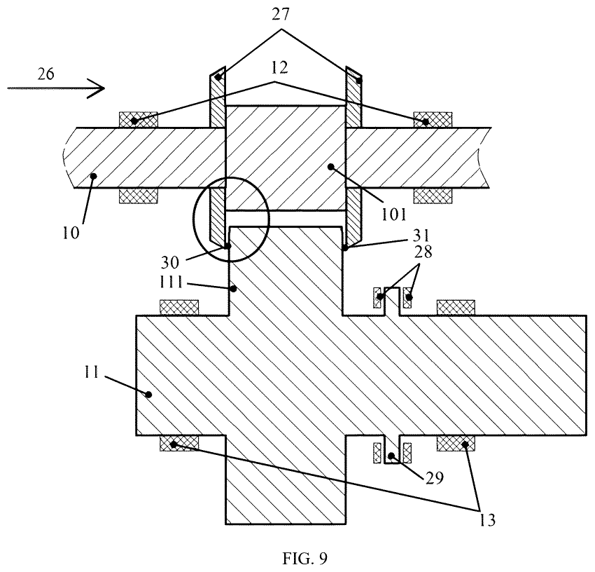

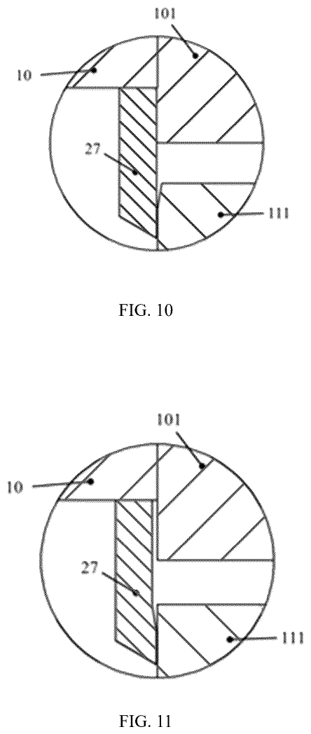

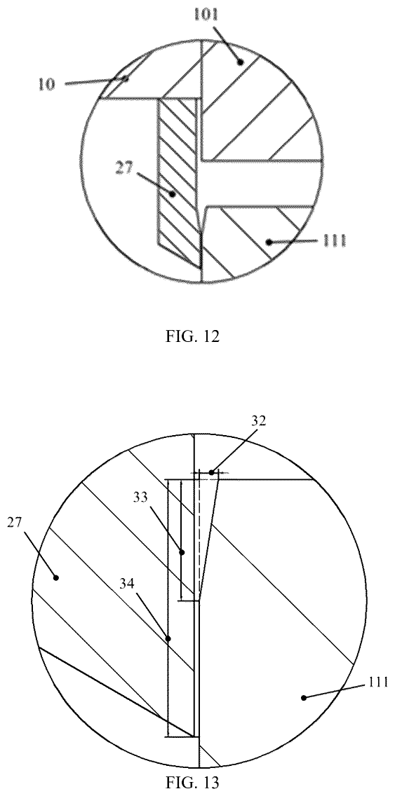

In an optional implementation of the present application, as shown in FIG. 9 to FIG. 13, a fluid dynamic pressure gap is provided between the high-speed shaft gear 101 and the low-speed shaft gear 111 in the gearbox of the supercritical carbon dioxide compressor. The gear thrust is adjusted by means of the fluid dynamic pressure gap, as follows.

In the supercritical carbon dioxide compressor, axial thrust plates 27 are added on both sides of the high-speed shaft gear 101 in the gearbox.

Each axial thrust plate 27 is closely fitted with the high-speed shaft gear 101, and is clearance-fitted with the low-speed shaft gear 111, forming a fluid dynamic pressure gap.

The thrust force of the high-speed shaft gear 101 is transmitted to the low-speed shaft gear 111 through the fluid dynamic pressure effect generated by the two fluid dynamic pressure gaps.

A thrust plate 29 and a thrust bearing 28, which are aligned and fitted on the low-speed shaft 11, balance the thrust of the low-speed shaft gear 111 through the thrust plate 29 and the thrust bearing 28.

In this embodiment, the axial thrust plates 27 are added to both sides of the high-speed shaft gear 101 in the gearbox, creating a fluid dynamic pressure gap between the axial thrust plate 27 and the low-speed shaft gear 111 to ensure thrust transmission. Then, thrust plate 29 and thrust bearing 28 are arranged on the low-speed shaft to balance the thrust. This successfully achieves thrust balance on the low-speed shaft 11 of the compressor. Since the frictional power loss caused by bearing thrust is proportional to the square of the rotational speed, this method of transmitting and balancing the thrust on the low-speed shaft significantly improves the frictional power loss of the thrust bearings, thereby enhancing the efficiency of the gearbox and the overall output power of the compressor unit. On the other hand, transferring the thrust to the low-speed shaft 11 can effectively reduce the number of thrust bearings required, shorten the axial span, and reduce the need for bearing lubrication, especially in situations where thrust bearings are arranged on multiple high-speed shafts.

In an embodiment, the inner side wall of the axial thrust plate 27 and/or the outer side wall of the low-speed shaft gear 111 are machined with wedge surfaces. The wedge surface is the core key to generating the fluid dynamic pressure effect. In this embodiment, wedge surfaces are machined on the axial thrust plates 27 on both sides of the high-speed shaft gear 101, on the low-speed shaft gear 111, or on both the axial thrust plate 27 and the low-speed shaft gear 111.

Specifically, when the compressor generates a positive thrust 26, the gap 30 between the axial thrust plate 27 and the left side of the low-speed shaft gear 111 decreases, increasing the fluid dynamic pressure effect and thereby generating greater thrust. The gap 31 between the axial thrust plate 27 and the right side of the low-speed shaft gear 111 increases, reducing or even eliminating the fluid dynamic pressure effect, leading to a reduction in thrust or insufficient thrust generation. Thus, the thrust is transmitted through the change in the gaps on both sides of the axial thrust plate 27 and the low-speed shaft gear 111, in relation to the action and reaction forces. The transmitted thrust is balanced by the axial thrust plate 29 and thrust bearing 28 on the low-speed shaft 11 for both positive (from left to right) and negative thrust balancing. When the compressor generates a negative thrust, the gap 31 between the axial thrust plate 27 and the right side of the low-speed shaft gear 111 decreases, thereby generating a stronger fluid dynamic pressure effect and thrust, while the gap 30 between the axial thrust plate 27 and the left side of the low-speed shaft gear 111 increases, generating a weaker fluid dynamic pressure effect and smaller thrust. Through the relationship of the action and reaction forces between the axial thrust plate 27 and the low-speed shaft gear 111, the thrust on the high-speed shaft is transmitted via the axial thrust plate 27 and the low-speed shaft gear 111 to the low-speed shaft 11, and then transmitted to the low-speed shaft axial thrust plate 29 and thrust bearing 28 for thrust balancing. If there is more than one high-speed shaft, this thrust transmission method is still applicable, and the analysis can be conducted for each individual shaft.

In an embodiment, a ratio of a minimum oil film thickness to a maximum height 32 of the wedge surface is in a range of 0.8 to 1.0. When the ratio of the minimum oil film thickness to the maximum height of the wedge surface is too low, the fluid dynamic pressure effect increases, and the lubricating oil pressure between the axial thrust plate 27 and the low-speed shaft gear 111 significantly rises, thereby increasing the thrust. However, excessively high pressure will lead to increased frictional losses, resulting in poor economic efficiency. On the other hand, when the ratio of the minimum oil film thickness to the maximum height of the wedge surface is too high, the fluid dynamic pressure effect weakens, and the lubricating oil pressure between the axial thrust plate 27 and the low-speed shaft gear 111 decreases, thereby reducing the thrust. This may fail to meet the starting thrust requirements of the unit and the thrust requirements under wide load operation. Therefore, based on practical experience, it is most appropriate to select the ratio of the minimum oil film thickness to the maximum height of the wedge surface to be between 0.8 and 1.0.

In an embodiment, the axial clearance between the axial thrust plate 27 and the low-speed shaft gear 111 (left-side clearance 30 or right-side clearance 31) is designed to be between 0.15 and 0.25 mm.

In an embodiment, in order to make full use of the fluid dynamic pressure effect of the wedge surface to transmit greater thrust, the ratio of the radial height 33 of the wedge surface to the radial height 34 of the overlapping low-speed shaft gear is between 0.4 and 0.8.

In an embodiment, the ratio of the roughness of the wedge surface to the maximum height 32 of the wedge surface is less than or equal to 2%.

In an embodiment, the axial thrust plates 27 on both sides of the high-speed shaft gear 101 can move freely to the left or right to ensure that thrust is transmitted on both the right and left sides.

In an embodiment, the axial gap between the axial thrust plate 27 and the low-speed shaft gear 111 ranges from 0.15 to 0.25 mm.

In an embodiment, the thrust plate 29 on the low-speed shaft 11 is integrally machined with the low-speed shaft 11, which significantly improves the machining precision of the low-speed shaft 11, thus reducing assembly steps and improving the dynamic balance precision of the shaft system.

In an embodiment, in order to facilitate later replacement and maintenance, the axial thrust plate 27 is fixed to the high-speed shaft 10 by a sleeve assembly.

The design method for the supercritical carbon dioxide compressor proposed in the present application addresses the issue of rapid changes in the physical properties of carbon dioxide near the critical region, which leads to inaccurate property interpolation and difficulties in compressor design. Based on fluid similarity theory, the near-critical carbon dioxide is equivalently treated as an ideal fluid with specific property intervals to avoid the issue of abrupt changes in the physical properties in the near-critical carbon dioxide region. The compressor's rated and variable operating conditions are then designed based on the equivalent ideal fluid. Finally, the performance curve of the equivalent ideal fluid is scaled back to the performance curve of near-critical carbon dioxide according to the fluid similarity theory.

The design method for the supercritical carbon dioxide compressor proposed in the present application addresses the need to simplify the off-design condition calculation workload and to respond with rapid iteration. It performs off-design aerodynamic performance correction based on the performance curve at the design conditions. First, for the same speed, the inlet flow velocity is identified at the off-design condition on the original design performance curve. Then, based on this condition, the total static pressure ratio is corrected using the principle of constant enthalpy rise. Using an overall correction method, the total static isentropic efficiency found is modified to obtain the new off-design condition performance curve. This correction method allows the entire off-design performance curve to be obtained through a single off-design calculation simulation, significantly reducing the computation time and workload, and meeting the fast and high-frequency iteration requirements for system operation or simulation.

The design method for the supercritical carbon dioxide compressor proposed in the present application addresses the requirement for the safe operation of the gearbox and dry gas seal in the zero-leakage scenario of supercritical carbon dioxide. The method restricts the relationship between the temperature and pressure of the total gas flow upstream of the dry gas seal main flow and isolation gas flow split, ensuring that the temperature of the dry gas seal leakage gas and isolation gas outlet flow is close to the bearing inlet oil temperature. At the same time, additional pressure-reduction structures, other than the pressure-reducing valve, are introduced in the isolation gas flow branch to meet the requirement for gradual pressure reduction of the isolation gas flow, achieving a final large pressure drop while protect the pressure-reducing valve throat from frost.

The design method for the supercritical carbon dioxide compressor proposed in the present application addresses the issue of thrust balance with low power loss in the compressor. Thrust disks are added on both sides of the gearbox high-speed shaft gear, and a wedge-shaped surface is processed between the thrust disk and the low-speed shaft gear to form a fluid dynamic pressure gap, ensuring the transmission of thrust between the gears. Thrust disks and thrust bearings are then arranged on the low-speed shaft to achieve thrust balance. This setup successfully balances the compressor thrust on the low-speed shaft, effectively reducing the power loss of the thrust bearing.

The detailed explanation for the various embodiments above is intended solely to explain this application, so as to better understand it. However, these descriptions should not be interpreted as any form of limitation to the application for any reason. Specifically, the various features described in different embodiments may be freely combined to form other embodiments. Unless explicitly stated otherwise, these features should be understood to be applicable to any embodiment and are not limited to the ones described.

What is claimed is:

1. A design method for a supercritical carbon dioxide compressor, comprising:
obtaining a performance curve of the supercritical carbon dioxide compressor based on the fluid similarity theory;
performing off-design performance correction of the supercritical carbon dioxide compressor based on the performance curve of the compressor;
controlling a dry gas seal temperature of the supercritical carbon dioxide compressor based on a correspondence between temperature and pressure; and
providing a fluid dynamic pressure gap between a high-speed shaft gear and a low-speed shaft gear in a gearbox of the supercritical carbon dioxide compressor, and adjusting a gearbox thrust through the fluid dynamic pressure gap.

2. The design method for the supercritical carbon dioxide compressor according to claim 1, wherein the obtaining the performance curve of the supercritical carbon dioxide compressor based on the fluid similarity theory comprises:
equating each thermophysical property range of supercritical carbon dioxide to a corresponding thermophysical property range of an ideal working medium based on the fluid similarity theory;
performing rated operating condition design and off-design condition design of the compressor based on the ideal working fluid, and obtaining a performance curve of the ideal working fluid; and
scaling the performance curve of the compressor for the ideal working fluid back to the performance curve of the supercritical carbon dioxide compressor based on the fluid similarity theory.

3. The design method for the supercritical carbon dioxide compressor according to claim 2, wherein the performance index of the supercritical carbon dioxide comprises a pressure ratio, a mass flow rate, and an isentropic efficiency.

4. The design method for the supercritical carbon dioxide compressor according to claim 3, wherein the scaling the performance curve of the compressor for the ideal working medium back to the performance curve of the supercritical carbon dioxide compressor based on the fluid similarity theory comprises:
obtaining the pressure ratio of the supercritical carbon dioxide based on Prandtl similarity and by equating an isentropic head coefficient;
obtaining the mass flow rate of the supercritical carbon dioxide according to geometric similarity; and
obtaining the isentropic efficiency of the supercritical carbon dioxide according to an empirical approximation relationship.

5. The design method for the supercritical carbon dioxide compressor according to claim 2, wherein the fluid similarity theory comprises Reynolds number similarity, Prandtl similarity, geometric similarity, and an empirical approximation relationship.

6. The design method for the supercritical carbon dioxide compressor according to claim 5, wherein the Prandtl similarity requires that an isentropic head coefficient and a specific speed of the supercritical carbon dioxide compressor are equal.

7. The design method for the supercritical carbon dioxide compressor according to claim 5, wherein the geometric similarity is ensured by equal flow coefficient, volumetric flow rate and rotational speed.

8. The design method for the supercritical carbon dioxide compressor according to claim 1, wherein the performing off-design performance correction of the supercritical carbon dioxide compressor based on the performance curve of the compressor comprises:
drawing a performance curve graph of the supercritical carbon dioxide compressor under a design condition;
searching, at the same rotational speed, for an operating condition with a same inlet flow rate on the performance curve graph under the design condition; and
correcting the performance curve graph based on the operating condition with the same inlet flow rate to obtain the performance curve under an off-design condition.

9. The design method for the supercritical carbon dioxide compressor according to claim 8, wherein the performance curve graph at least comprises a total-to-static pressure ratio performance curve graph and a total-to-static isentropic efficiency performance curve graph.

10. The design method for the supercritical carbon dioxide compressor according to claim 9, wherein the total-to-static pressure ratio performance curve graph is corrected under a principle of constant enthalpy rise at the same inlet flow rate to obtain a total-to-static pressure ratio performance curve graph under the off-design condition.

11. The design method for the supercritical carbon dioxide compressor according to claim 10, wherein a surge line and a choke line are established on the total-to-static pressure ratio performance curve graph under the design condition based on a principle of constant inlet flow rate at the same rotational speed.

12. The design method for the supercritical carbon dioxide compressor according to claim 9, wherein the total-to-static isentropic efficiency performance curve graph is globally corrected according to an overall correction factor of the total-to-static isentropic efficiency to obtain the total-to-static isentropic efficiency performance curve graph under the off-design condition.

13. The design method for the supercritical carbon dioxide compressor according to claim 12, wherein the overall correction factor of the total-to-static isentropic efficiency is calculated by:
obtaining a design flow and a design rotational speed corresponding to a point of maximum total-to-static isentropic efficiency at a rated speed in the total-to-static isentropic efficiency performance curve graph under the design condition;
finding, according to a principle of equal inlet flow speed, a reference flow rate point under the off-design condition corresponding to the point of maximum total-to-static isentropic efficiency under the design condition, and calculating the total-to-static isentropic efficiency at the reference flow rate point; and
calculating the overall correction factor of the total-to-static isentropic efficiency based on the total-to-static isentropic efficiency at the reference flow rate point and the maximum total-to-static isentropic efficiency under the design condition.

14. The design method for the supercritical carbon dioxide compressor according to claim 13, wherein the reference flow rate point under the off-design condition is located based on a design flow rate at the point of maximum total-to-static isentropic efficiency at the rated speed, according to the principle of equal inlet flow speed.

15. The design method for the supercritical carbon dioxide compressor according to claim 13, wherein a simulation calculation is performed to obtain the converted total-to-static isentropic efficiency based on an inlet pressure, an inlet temperature, the flow rate at the reference flow rate point, and a converted rotational speed under the off-design condition.

16. The design method for the supercritical carbon dioxide compressor according to claim 15, wherein the design rotational speed is converted into the converted rotational speed at the reference flow rate point under the off-design condition according to a principle of constant rotational speed.

17. The design method for the supercritical carbon dioxide compressor according to claim 13, wherein the overall correction factor of the total-to-static isentropic efficiency is a ratio of the total-to-static isentropic efficiency at the reference flow rate point to the maximum total-to-static isentropic efficiency under the design condition.

18. The design method for the supercritical carbon dioxide compressor according to claim 1, wherein controlling the dry gas seal temperature of the supercritical carbon dioxide compressor based on the correspondence between temperature and pressure comprises:
suspending a dry gas seal device for implementing dry gas sealing on the gearbox of the supercritical carbon dioxide compressor, and introducing an injection gas flow into the dry gas seal device, wherein a relationship between pressure and temperature of the injection gas flow is as follows:
$${T}_{min} = - 0.0032 {P}^{3} + 0.0041 {P}^{2} + 6.0759 P + 42.262 ; and$$
$${T}_{max} = 0.0118 {P}^{3} - 0.5304 {P}^{2} + 11.581 P + 48.113 ;$$
wherein Tₘᵢₙ is a lowest temperature of the introduced injection gas flow; Tₘₐₓ is a highest temperature of the introduced injection gas flow; and P is the pressure of the introduced injection gas flow.

19. The design method for the supercritical carbon dioxide compressor according to claim 18, wherein an applicable range of the pressure of the injection ranges from 6 MPa to 20 MPa.

20. The design method for the supercritical carbon dioxide compressor according to claim 18, wherein the injection gas flow is split into a main gas flow and an isolation gas flow after being introduced into the dry gas seal device.

21. The design method for the supercritical carbon dioxide compressor according to claim 20, wherein a flow resistance member, a pressure relief valve, and a throttling hole are sequentially arranged along a flow direction of the isolation gas flow, and the isolation gas flow is stepwise depressurized through the flow resistance member, the pressure relief valve, and the throttling hole.

22. The design method for the supercritical carbon dioxide compressor according to claim 21, wherein a pressure drop distribution principle of the isolation gas flow is that a minimum isentropic expansion temperature at a throat of the pressure relief valve is higher than zero degrees Celsius.

23. The design method for the supercritical carbon dioxide compressor according to claim 1, wherein:
axial thrust plates are respectively added to both sides of the high-speed shaft gear of the gearbox of the supercritical carbon dioxide compressor;
the axial thrust plate are tightly fitted to the high-speed shaft gear, and clearance-fitted with the low-speed shaft gear to form fluid dynamic pressure gaps;
a thrust force of the high-speed shaft gear is transmitted to the low-speed shaft gear through fluid dynamic pressure effect generated by the two fluid dynamic pressure gaps; and
a thrust plate and a thrust bearing are aligned on the low-speed shaft to balance the thrust force of the low-speed shaft gear.

24. The design method for the supercritical carbon dioxide compressor according to claim 23, wherein a wedge surface is machined on an inner side wall of the axial thrust plate and/or an outer side wall of the low-speed shaft gear.

25. The design method for the supercritical carbon dioxide compressor according to claim 24, wherein a ratio of a minimum oil film thickness in the gearbox to a maximum height of the wedge surface ranges from 0.8 to 1.0.

26. The design method for the supercritical carbon dioxide compressor according to claim 23, wherein an axial gap between the axial thrust plate and the low-speed shaft gear ranges from 0.15 mm to 0.25 mm.
